(19) United States
(12) Patent Application Publication
(10) Pub. No.: US 2012/0292630 A1
(43) Pub. Date: Nov. 22, 2012

(54) LED SUBSTRATE AND LED

(75) Inventors: Yew-Chung Sermon Wu, Hsinchu City (TW); Feng-Ching Hsiao, Hsinchu City (TW); Yu-Chung Chen, Hsinchu City (TW); Bo-Hsiang Tseng, Hsinchu City (TW); Bo-Wen Lin, Hsinchu City (TW); Chun-Yen Peng, Hsinchu City (TW); Wen-Ching Hsu, Hsinchu City (TW)

(73) Assignee: SINO-AMERICAN SILICON PRODUCTS INC., Hsinchu City (TW)

(21) Appl. No.: 13/154,445

(22) Filed: Jun. 7, 2011

(30) Foreign Application Priority Data
May 16, 2011 (TW) 100117040

(51) Int. Cl. H01L 33/22; H01L 33/30

(52) U.S. Cl. 257/76; 257/98; 257/E33.074

(57) ABSTRACT

A light emitting diode (LED) substrate including a sapphire substrate is provided. The sapphire substrate has a surface consisting of a plurality of upper trigonal and lower hexagonal tapers, wherein each of the upper trigonal and lower hexagonal tapers is consisted of a hexagonal taper and a trigonal taper on the hexagonal taper, and a pitch of the upper trigonal and lower hexagonal tapers is less than 10 μm. This LED substrate has high light-emitting efficiency.

### CROSS-REFERENCE TO RELATED APPLICATION

This application claims the priority benefit of Taiwan application serial no. 100117040, filed May 16, 2011. The entirety of the above-mentioned patent application is hereby incorporated by reference herein and made a part of this specification.

### BACKGROUND OF THE INVENTION

1. Field of the Invention

The invention relates to a light emitting diode (LED) substrate. Particularly, the invention relates to a LED substrate having high light extraction efficiency and an LED using the same.

2. Description of Related Art

LED is a light-emitting device fabricated by a compound semiconductor, in which electric energy can be converted into light through combination of electrons and holes. The LED is belonged to a cold light source, and has advantages of low power consumption, none warm up time, long service life and fast response speed, etc., and further has features of high impact resistance and suitable for mass production, and consequently it is easy to meet application requirements to fabricate extremely small or array devices.

In order to expand the application range and future of the LED, it is one of the research focuses to improve a light-emitting brightness of the LED. In an ideal LED, after carriers in an active region are recombined into photons, if these photons can all be propagated to external, the light emitting efficiency of such LED is 100%. However, the photons generated in the active region cannot be propagated to external by 100% due to various depletion mechanisms.

In order to improve the light-emitting efficiency of the LED, a patterned LED substrate, for example, the LED substrate formed by a plurality of cones or platform structures is used to scatter the light emitted from the LED, so as to reduce a total reflection.

### SUMMARY OF THE INVENTION

The invention is directed to a light emitting diode (LED) substrate, which has high light emitting efficiency.

The invention also provides a LED, which uses the aforementioned LED substrate.

The invention provides a LED substrate, which includes a sapphire substrate having a surface consisting of a plurality of upper trigonal and lower hexagonal tapers, wherein each of the upper trigonal and lower hexagonal tapers is consisted of a hexagonal taper and a trigonal taper on the hexagonal taper, and a pitch of the upper trigonal and lower hexagonal tapers is less than 10 μm.

In an embodiment of the invention, the pitch of the upper trigonal and lower hexagonal tapers has a ranging from 1 μm to 4 μm.

In an embodiment of the invention, a maximum height of each of the upper trigonal and lower hexagonal tapers has a ranging from 1 μm to which is preferably from 1.5 μm to 2 μm.

In an embodiment of the invention, a top of the trigonal taper is a plane or a pointed end.

In an embodiment of the invention, a symmetric cross-section of the trigonal taper has a first base angle and a second base angle, the second base angle is greater than the first base angle, and the second base angle is between 28 degrees and 32 degrees.

In an embodiment of the invention, a symmetric cross-section of the hexagonal taper with the trigonal taper thereon has a third base angle and a fourth base angle, wherein the fourth base angle is greater than the third base angle, and the fourth base angle is between 50 degrees and 70 degrees.

In an embodiment of the invention, the surface of the sapphire substrate includes a (0001) surface, and an area of the (0001) surface is about 10-60% of a projected area of the surface of the sapphire substrate, which is preferably 10-30%.

The invention further provides a LED including the aforementioned sapphire substrate, a first semiconductor layer stacked overlaying the sapphire substrate, a light emitting layer stacked overlaying the first semiconductor layer, a second semiconductor layer stacked overlaying the light emitting layer, a first ohmic electrode contacting the first semiconductor layer and a second ohmic electrode contacting the second semiconductor layer.

In an embodiment of the invention, the first semiconductor layer, the light emitting layer and the second semiconductor layer include a III-V semiconductor, for example, a gallium nitride semiconductor.

In an embodiment of the invention, the first and the second ohmic electrodes are respectively at least one alloy or a multi-layer film selected from the group consisting of Ni, Pb, Co, Fe, Ti, Cu, Rh, Au, Ru, W, Zr, Mo, Ta, Ag, oxides thereof, and nitrides thereof.

In an embodiment of the invention, the first and the second ohmic electrodes are respectively an alloy or a multi-layer film selected from the group consisting of Rh, Ir, Ag and Al.

According to the above disclosure, the sapphire substrate has a light emitting surface consisted of a plurality of upper trigonal and lower hexagonal tapers, and nine surfaces of the upper trigonal and lower hexagonal taper can be used to scatter the light, so as to improve the light emitting efficiency of the substrate.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a three-dimensional view of a light emitting diode (LED) substrate according to a first embodiment of the invention.

FIG. 2A is a three-dimensional view of a single upper trigonal and lower hexagonal taper according to the first embodiment of the invention.

FIG. 2B is a cross-sectional view of the upper trigonal and lower hexagonal taper of FIG. 2A along a B-B line.

FIGS. 3A-3F are schematic diagrams illustrating two fabrication flows of a LED substrate of the first embodiment.

FIG. 4 is a scanning electron microscope (SEM) photograph of a sapphire substrate fabricated according to the steps of FIGS. 3A-3F.

FIG. 5 is a top view SEM photograph of the LED substrate of FIG. 4.

FIG. 6 is a cross-sectional view of a LED according to a second embodiment of the invention.

FIG. 7 is a diagram illustrating a detailed size of a substrate consisted of conventional cones in a simulation test.

FIG. 8 is a diagram illustrating a detailed size of a substrate consisted of conventional platform structures in a simulation test.

FIG. 9 is a diagram illustrating a detailed size of a substrate consisted of upper trigonal and lower hexagonal tapers in a simulation test.

### DETAILED DESCRIPTION OF DISCLOSED EMBODIMENTS

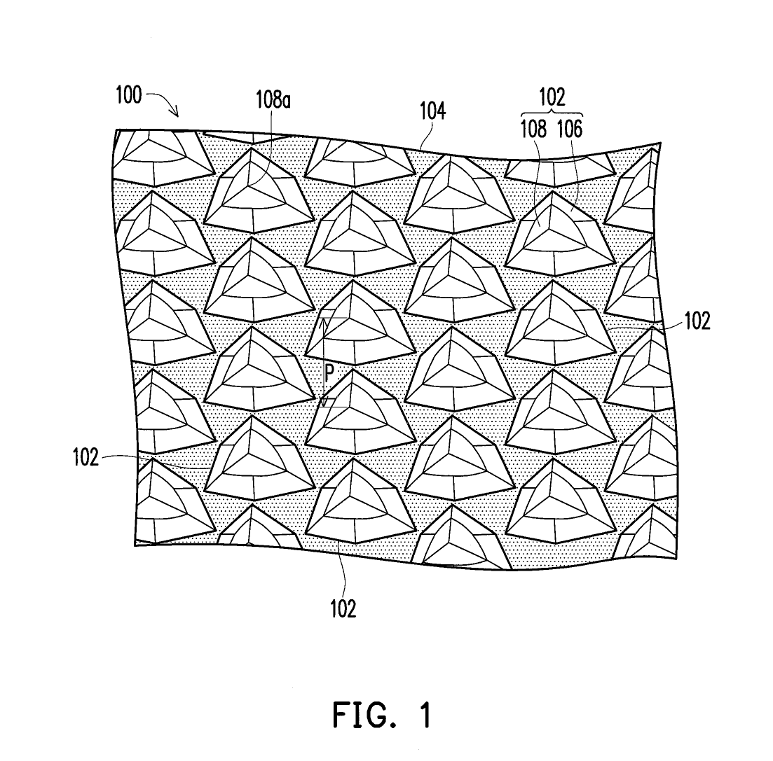

FIG. 1 is a three-dimensional view of a light emitting diode (LED) substrate according to a first embodiment of the invention. In FIG. 1, a sapphire substrate 100 is illustrated. The sapphire substrate 100 includes a surface 104 consisting of a plurality of upper trigonal and lower hexagonal tapers 102, where each of the upper trigonal and lower hexagonal tapers 102 is consisted of a hexagonal taper 106 and a trigonal taper 108 on the hexagonal taper 106, and a pitch P of the upper trigonal and lower hexagonal tapers 102 is less than 10 μm, which is preferably between 1 μm and 4 μm. The so-called “pitch” refers to a distance between two adjacent upper trigonal and lower hexagonal tapers 102.

In FIG. 1, a top 108a of the trigonal taper 108 is a pointed end. However, the invention is not limited thereto, and the top 108a of the trigonal taper 108 can also be a platform surface, though the pointed end may have better light emitting efficiency. For example, the surface 104 of the sapphire substrate 100 includes a (0001) surface (i.e. a surface distributed with dots in FIG. 1), and an area of the (0001) surface is 10-60% of a projected area of the surface 104, which is preferably 10-30%. When the area of the (0001) surface is more than 60% of the projected area of the surface 104, a gain of the light emitting efficiency is probably low, though when the area of the (0001) surface is less than 10% of the projected area of the surface 104, it may cause difficult in epitaxy.

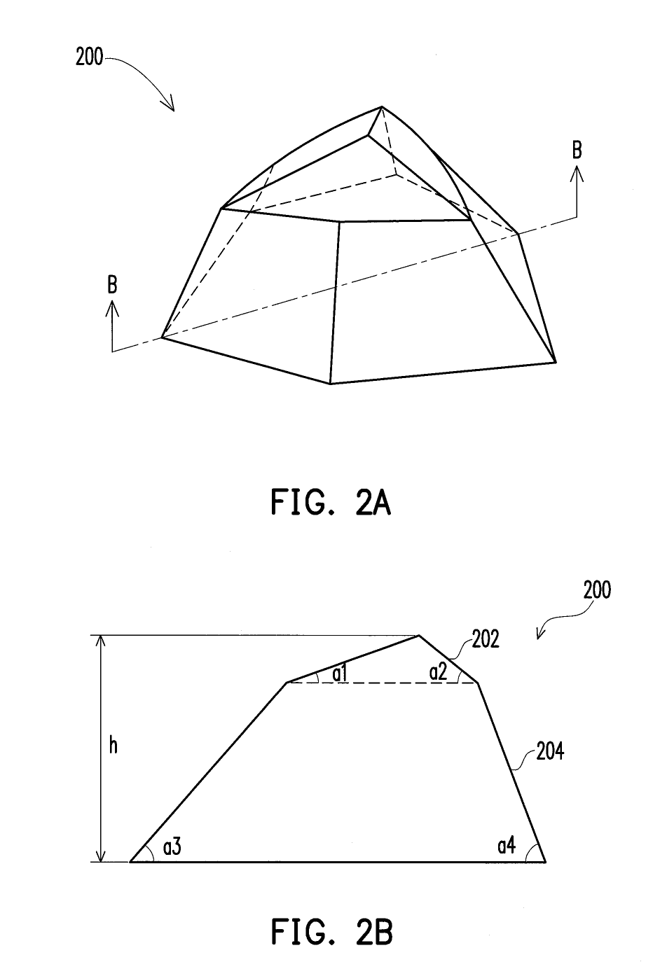

FIG. 2A is a three-dimensional view of a single upper trigonal and lower hexagonal taper according to the first embodiment of the invention. FIG. 2B is a cross-sectional view of the upper trigonal and lower hexagonal taper of FIG. 2A along a B-B line.

Referring to FIG. 2A and FIG. 2B, a maximum height h of the upper trigonal and lower hexagonal taper 200 is, for example, proportional to the pitch of the upper trigonal and lower hexagonal taper 200. The so-called “maximum height” refers to a distance between the top of a trigonal taper 202 to the bottom of a hexagonal taper 204. In the present embodiment, the maximum height of the upper trigonal and lower hexagonal taper 200, for example, has a ranging from 1 μm to 2 μm, which is preferably from 1.5 μm to 2 μm. When the maximum height of the upper trigonal and lower hexagonal taper 200 is greater than 2 μm, it may cause difficult in epitaxy. A symmetric cross-section of the trigonal taper 202 of the upper trigonal and lower hexagonal taper 200 has a first base angle a1 and a second base angle a2, the second base angle a2 is greater than the first base angle a1, and the second base angle a2 is, for example, between 28 degrees and 32 degrees. A symmetric cross-section of the hexagonal taper 204 has a third base angle a3 and a fourth base angle a4, wherein the fourth base angle a4 is greater than the third base angle a3, and the fourth base angle a4 is between 50 degrees and 70 degrees, which is preferably between 55 degrees and 65 degrees.

Two experimental examples for manufacturing the LED substrate of the first embodiment are provided below.

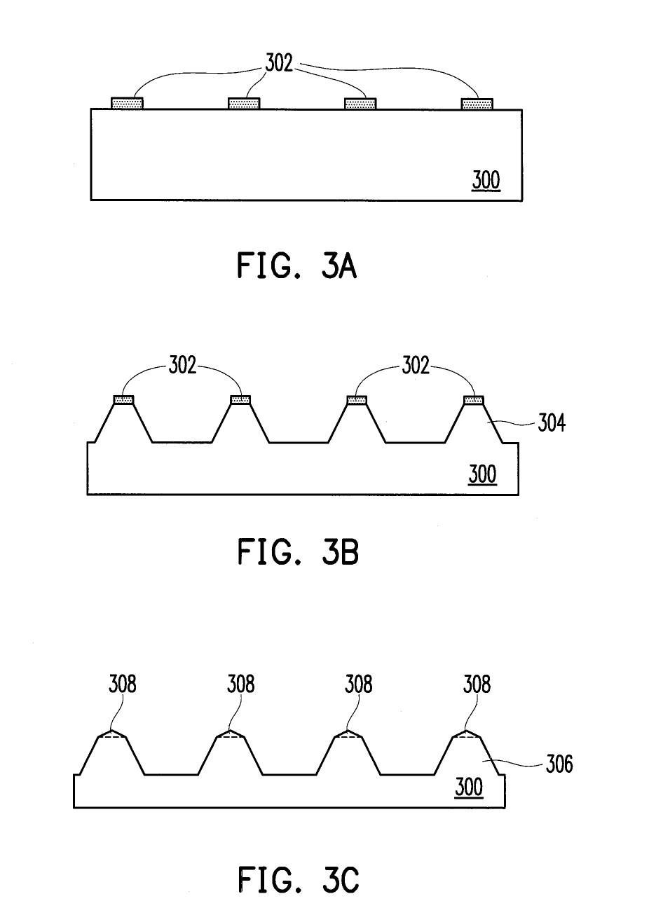

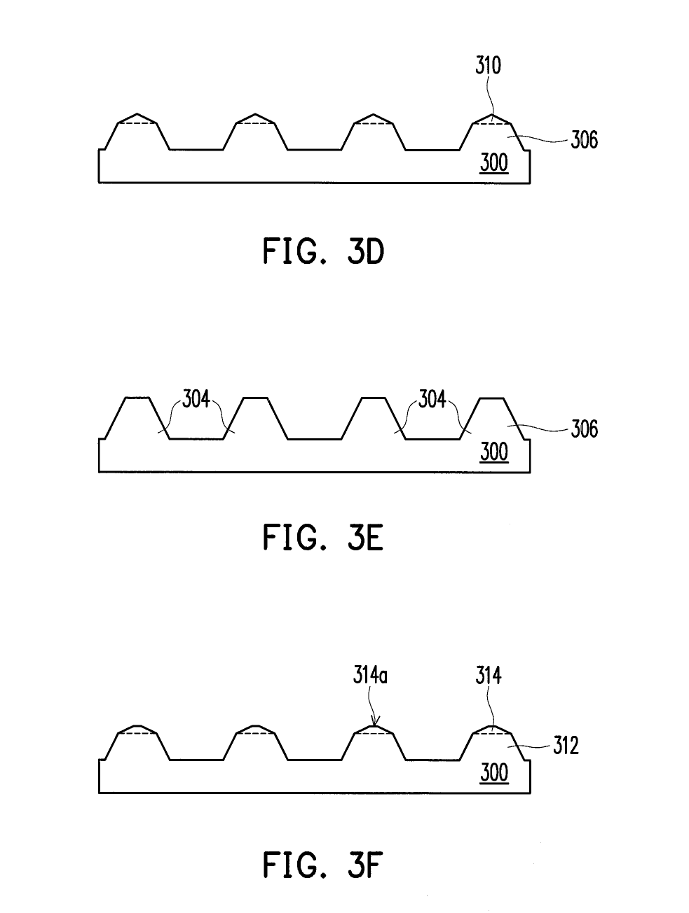

FIGS. 3A-3D are schematic diagrams illustrating a fabrication flow of the LED substrate of the first embodiment.

First, a sapphire substrate 300 is provided, and then a hard mask 302 with a pattern is formed on the sapphire substrate 300, as that shown in FIG. 3A. Then, adhesion between the hard mask 302 and the sapphire substrate 300 can be enhanced through an existing technique if necessary, so as to facilitate a post etching process to increase an etching resistance capability.

Then, a wet etching process of about several minutes is performed. During the etching process, the sapphire substrate 300 is first formed with protrusion patterns 304 of a hexagonal taper array, as that shown in FIG. 3B.

After the hard mask 302 is etched to form hexagonal tapers 306, an etching fluid continually etches the sapphire substrate 300 to form trigonal tapers 308 on the hexagonal tapers 306 as shown in FIG. 3C.

As time goes on, the height of the hexagonal tapers 306 is gradually decreased until the hexagonal tapers 306 disappear, so that an etching stop time is controlled to ensure that the sapphire substrate 300 is formed with upper trigonal and lower hexagonal tapers consisted of the hexagonal tapers 306 and trigonal tapers 310. In FIG. 3D, the greater base angle of the hexagonal taper 306 is 58 degrees, so that crystal surfaces of the hexagonal taper 306 are (3140), (3410), (4130), (1430), (1340), (4310); the greater base angle of the trigonal taper 310 is 31 degrees, so that crystal surfaces of the trigonal taper 308 are (1105), (1015), (0115).

Moreover, after the process shown in FIG. 3B, the hard mask 302 may be optionally removed, as that shown in FIG. 3E. Thereafter, another wet etching process of several minutes is performed on the sapphire substrate 300 to form hexagonal tapers 312 and trigonal tapers 314 thereon, where a top 314a of the trigonal taper 314 may be a plane as shown in FIG. 3F.

Experimental examples of manufacturing the LED substrate of the invention are described as above, though the above processes are not used to limit the invention, and those skilled in the art can fabricate the structure of the invention through existing techniques according to the above descriptions.

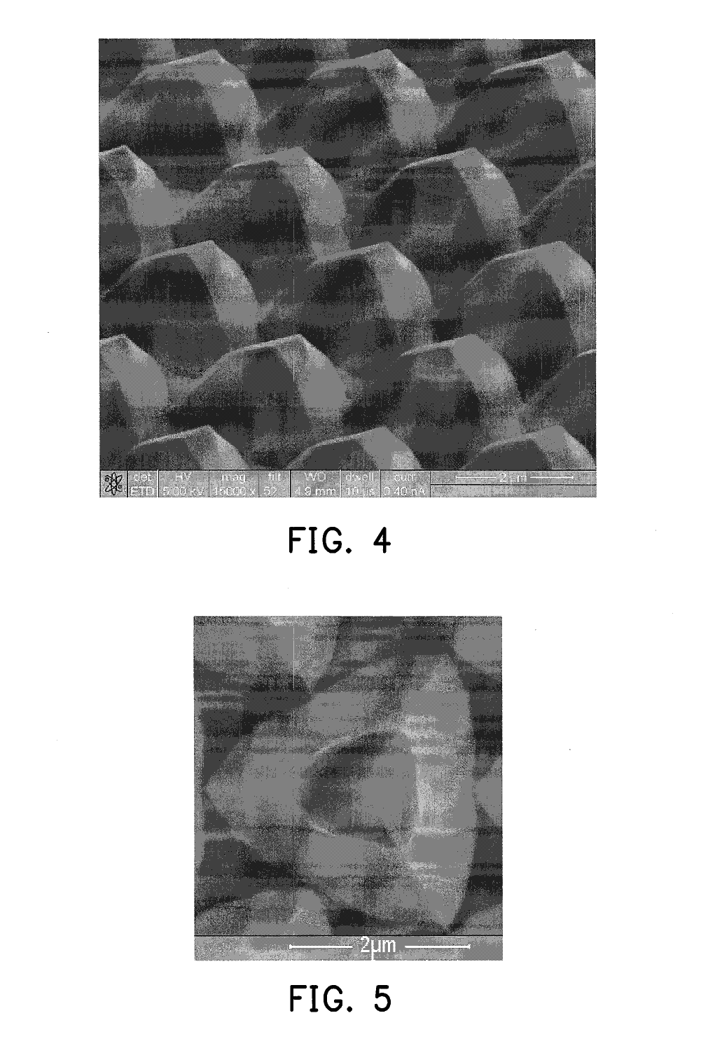

FIG. 4 is a scanning electron microscope (SEM) photograph of a sapphire substrate fabricated according to the above steps, and FIG. 5 is a top view SEM photograph of the LED substrate of FIG. 4. According to FIG. 5, a boundary between the hexagonal taper and the trigonal taper thereon of the upper trigonal and lower hexagonal taper can be clearly observed.

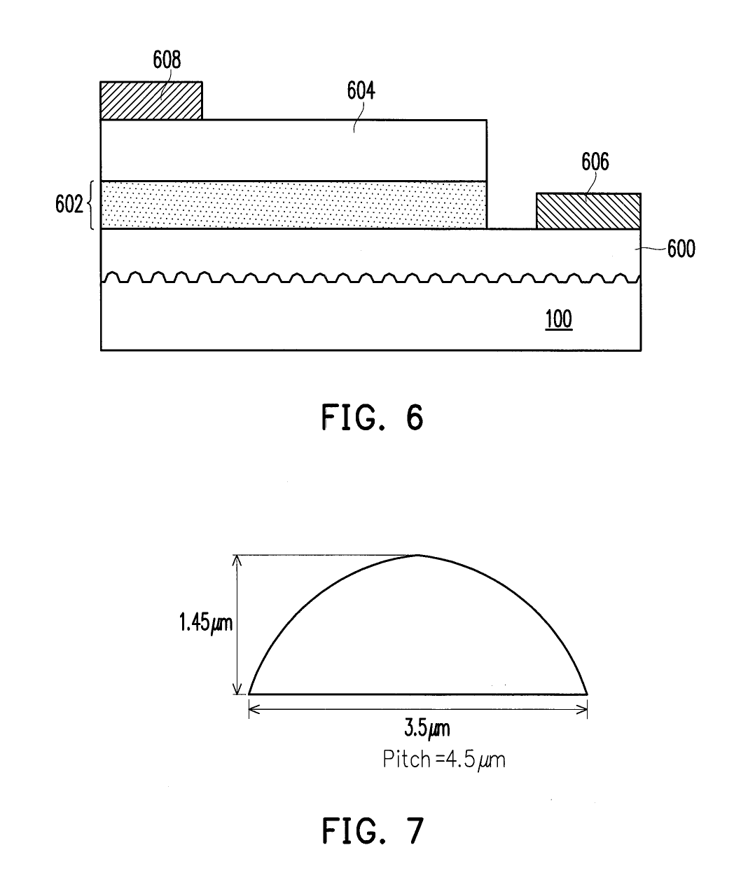

FIG. 6 is a cross-sectional view of a LED according to a second embodiment of the invention. In FIG. 6, a sapphire substrate 100 of the first embodiment (referring to FIG. 1), a first semiconductor layer 600 stacked overlaying the sapphire substrate 100, a light emitting layer 602 stacked overlaying the first semiconductor layer 600, a second semiconductor layer 604 stacked overlaying the light emitting layer 602, a first ohmic electrode 606 contacting the first semiconductor layer 600 and a second ohmic electrode 608 contacting the second semiconductor layer 604 are illustrated. In the present embodiment, the first semiconductor layer 600, the light emitting layer 602 and the second semiconductor layer 604 can be a III-V semiconductor, for example, a gallium nitride semiconductor. The first and the second ohmic electrodes 606 and 608 are respectively at least one alloy or a multi-layer film selected from the group consisting of Ni, Pb, Co, Fe, Ti, Cu, Rh, Au, Ru, W, Zr, Mo, Ta, Ag, oxides thereof, and nitrides thereof. Moreover, each of the first and the second ohmic electrodes 606 and 608 can also be an alloy or a multi-layer film selected from the group consisting of Rh, Ir, Ag and Al.

In order to verify the effect of the LED substrate of the above embodiment, light emitting efficiencies of the LED of FIG. 6 using different LED substrates are simulated.

### Simulation Test

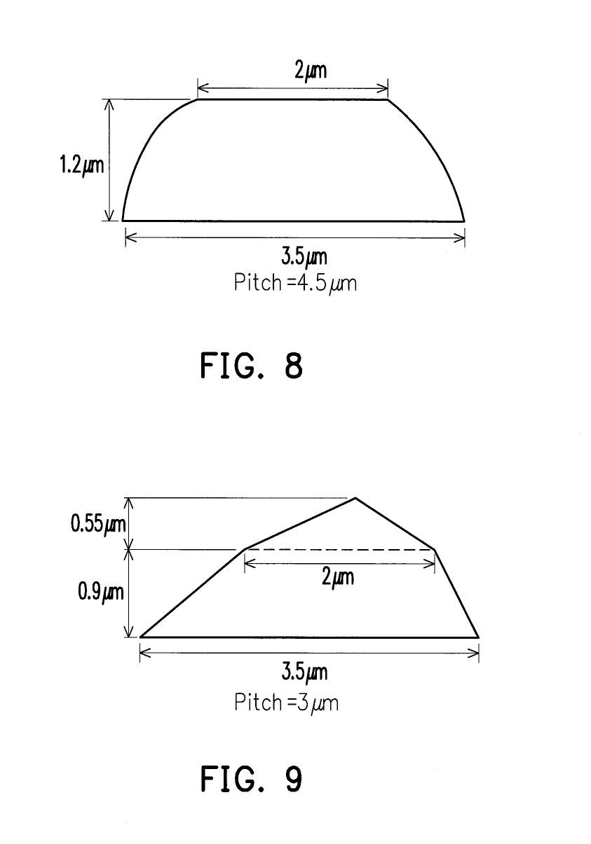

First, it is assumed that the first semiconductor layer 600 is n-GaN, the light emitting layer 602 is a multiple quantum well (MQW) structure, and the second semiconductor layer 604 is p-GaN. Three types of the LED substrates including a substrate consisted of the conventional cones of FIG. 7, a substrate consisted of the conventional platform structures of FIG. 8 and the substrate consisted of the upper trigonal and lower hexagonal tapers of the first embodiment (referring to FIG. 9) are provided. Surface structures of FIG. 7 and FIG. 8 are all fabricated through a dry etching process.

According to a simulation result, it is known that a light emitting efficiency of FIG. 7 is 128.2%, a light emitting efficiency of FIG. 8 is 130.5% and a light emitting efficiency of FIG. 9 is 135.5%, so that regarding the light emitting efficiency, the substrate consisted of the upper trigonal and lower hexagonal tapers is better than the substrate consisted of the conventional platform structures and the substrate consisted of the conventional cones.

In summary, in the LED substrate of in the invention, the sapphire substrate consisted of a plurality of the upper trigonal and lower hexagonal tapers serves as a light emitting surface, and the upper trigonal and lower hexagonal taper form a nine surfaces can be used to scatter the light. Therefore, the light emitting efficiency of the LED using the LED substrate of the invention is improved.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A light emitting diode (LED) substrate, comprising:
a sapphire substrate, having a surface consisting of a plurality of upper trigonal and lower hexagonal tapers, wherein each of the upper trigonal and lower hexagonal tapers is consisted of a hexagonal taper and a trigonal taper on the hexagonal taper, and a pitch of the upper trigonal and lower hexagonal tapers is less than 10 μm.

2. The LED substrate as claimed in claim 1, wherein the pitch of the upper trigonal and lower hexagonal tapers has a ranging from 1 μm to 4 μm.

3. The LED substrate as claimed in claim 1, wherein a maximum height of each of the upper trigonal and lower hexagonal tapers has a ranging from 1 μm to 2 μm.

4. The LED substrate as claimed in claim 3, wherein the maximum height of each of the upper trigonal and lower hexagonal tapers has a ranging from 1.5 μm to 2 μm.

5. The LED substrate as claimed in claim 1, wherein a top of the trigonal taper is a plane or a pointed end.

6. The LED substrate as claimed in claim 1, wherein a symmetric cross-section of the trigonal taper has a first base angle and a second base angle, the second base angle is greater than the first base angle, and the second base angle is between 28 degrees and 32 degrees.

7. The LED substrate as claimed in claim 1, wherein a symmetric cross-section of the hexagonal taper has a third base angle and a fourth base angle, the fourth base angle is greater than the third base angle, and the fourth base angle is between 50 degrees and 70 degrees.

8. The LED substrate as claimed in claim 1, wherein the surface comprises a (0001) surface, and an area of the (0001) surface is 10-60% of a projected area of the surface.

9. The LED substrate as claimed in claim 8, wherein the surface comprises the (0001) surface, and the area of the (0001) surface is 10-30% of the projected area of the surface.

10. A light emitting diode (LED), comprising:
a sapphire substrate, having a surface consisting of a plurality of upper trigonal and lower hexagonal tapers, wherein each of the upper trigonal and lower hexagonal tapers is consisted of a hexagonal taper and a trigonal taper on the hexagonal taper, and a pitch of the upper trigonal and lower hexagonal tapers is less than 10 μm
a first semiconductor layer, stacked overlaying the sapphire substrate;
a light emitting layer, stacked overlaying the first semiconductor layer;
a second semiconductor layer, stacked overlaying the light emitting layer;
a first ohmic electrode, contacting the first semiconductor layer; and
a second ohmic electrode, contacting the second semiconductor layer.

11. The LED as claimed in claim 10, wherein the pitch of the upper trigonal and lower hexagonal tapers has a ranging from 1 μm to 4 μm.

12. The LED as claimed in claim 10, wherein a maximum height of each of the upper trigonal and lower hexagonal tapers has a ranging from 1 μm to 2 μm.

13. The LED as claimed in claim 12, wherein the maximum height of each of the upper trigonal and lower hexagonal tapers has a ranging from 1.5 μm to 2 μm.

14. The LED as claimed in claim 10, wherein a top of the trigonal taper is a plane or a pointed end.

15. The LED as claimed in claim 10, wherein a symmetric cross-section of the trigonal taper has a first base angle and a second base angle, the second base angle is greater than the first base angle, and the second base angle is between 28 degrees and 32 degrees.

16. The LED as claimed in claim 10, wherein a symmetric cross-section of the hexagonal taper has a third base angle and a fourth base angle, the fourth base angle is greater than the third base angle, and the fourth base angle is between 50 degrees and 70 degrees.

17. The LED substrate as claimed in claim 10, wherein the surface comprises a (0001) surface, and an area of the (0001) surface is 10-60% of a projected area of the surface.

18. The LED substrate as claimed in claim 17, wherein the surface comprises the (0001) surface, and the area of the (0001) surface is 10-30% of the projected area of the surface.

19. The LED substrate as claimed in claim 10, wherein the first semiconductor layer, the light emitting layer and the second semiconductor layer comprise a III-V semiconductor.

20. The LED substrate as claimed in claim 19, wherein the III-V semiconductor is a gallium nitride semiconductor.

21. The LED substrate as claimed in claim 10, wherein the first and the second ohmic electrodes are respectively at least one alloy or a multi-layer film selected from the group consisting of Ni, Pb, Co, Fe, Ti, Cu, Rh, Au, Ru, W, Zr, Mo, Ta, Ag, oxides thereof, and nitrides thereof.

22. The LED substrate as claimed in claim 10, wherein the first and the second ohmic electrodes are respectively an alloy or a multi-layer film selected from the group consisting of Rh, Ir, Ag and Al.
